(19) United States
(12) Patent Application Publication
(10) Pub. No.: US 2012/0286373 A1
(43) Pub. Date: Nov. 15, 2012

(54) GATE STRUCTURE AND METHOD FOR MANUFACTURING THE SAME

(76) Inventors: Huicai Zhong, San Jose, CA (US); Zhijiong Luo, Poughkeepsie, NY (US); Qingqing Liang, Lagrangeville, NY (US)

(21) Appl. No.: 13/376,501

(22) PCT Filed: Apr. 26, 2011
(86) PCT No.: PCT/CN2011/073308

§ 371 Date: Dec. 6, 2011

(30) Foreign Application Priority Data
Mar. 4, 2011 (JP) 201110052271.8

(51) Int. Cl. H01L 29/78; H01L 21/336

(52) U.S. Cl. 257/410; 438/591; 257/E29.255; 257/E21.409

(57) ABSTRACT

Gates structures and methods for manufacturing the same are disclosed. In an example, the gate structure comprises a gate stack formed on a semiconductor substrate, the gate stack comprising a high-K dielectric layer and a metal gate electrode from bottom to top; a first dielectric layer on sidewalls of the gate stack, the first dielectric layer serving as first sidewall spacers; and a sacrificial metal layer on the first dielectric layer, the sacrificial metal layer serving as second sidewall spacers. The sacrificial metal layer in the gate structure reduces a thickness of an interfacial oxide layer in the step of annealing. The gate structure may be applied to a semiconductor device having a small size because the gate dielectric layer has a low EOT value.

### CROSS-REFERENCE TO RELATED APPLICATIONS

This application claims priority to the Chinese Patent Application No. 201110052271.8, filed on Mar. 4, 2011, entitled “GATE STRUCTURE AND METHOD FOR MANUFACTURING THE SAME”, which is incorporated herein by reference in its entirety.

### TECHNICAL FIELD

The present invention relates to semiconductor technology, and more particularly, to semiconductor devices and methods for manufacturing the same, and more particularly, to gate structures comprising a sacrificial metal layer and methods for manufacturing the same.

### BACKGROUND

Conventional processes for manufacturing CMOSFETs (Complementary Metal Oxide Semiconductor Field Effect Transistors) include a gate-first process and a gate-last process. In a process at 32 nm technology node and beyond, a stack structure of a high dielectric constant (high-K) dielectric/a metal gate electrode is widely used to provide a low equivalent oxide thickness (EOT). However, an interfacial oxide layer exists between the high-K dielectric and a channel region in a semiconductor substrate (typically made of silicon (Si) or germanium (Ge)). The dielectric layer between the metal gate electrode and the semiconductor substrate has the EOT value which is actually equal to a sum of the EOT value of the high-K dielectric layer and the EOT value of the interfacial oxide layer. Because the interfacial oxide layer itself has the EOT value of about 4 Å, it is difficult to provide the EOT value less than 1 nm.

In a conventional process for manufacturing CMOSFETs, a sacrificial metal layer (such as Ta, Ti, or the like) is deposited between the high-K dielectric and the metal gate electrode to remove oxygen in a thin dielectric film, for reducing the thickness of the interfacial oxide layer and thus the EOT value of the gate dielectric in the gate structure.

FIG. 1 schematically shows a conventional semiconductor device comprising a sacrificial metal layer. As shown in FIG. 1, the semiconductor device manufactured with a conventional process mainly comprises: a semiconductor substrate 101, a shallow trench isolation (STI) 102, an interfacial oxide layer 103, a high-K dielectric layer 104, a sacrificial metal layer 105 and a metal gate electrode 106. The STI 102 is formed in the semiconductor substrate 101 to isolate active regions of adjacent semiconductor devices. The interfacial oxide layer 103 is formed on the semiconductor substrate 101. The high-K dielectric layer 104 is formed on the interfacial oxide layer 103. The sacrificial metal layer 105 is formed on top of the high-K dielectric layer 104. The metal gate electrode 106 is formed on the sacrificial metal layer 105. In this way, a gate stack of the semiconductor device comprises the interfacial oxide layer 103, the high-K dielectric layer 104, the sacrificial metal layer 105 and the metal gate electrode 106.

In the semiconductor device shown in FIG. 1, the sacrificial metal layer 105 is deposited between the high-K dielectric layer 104 and the metal gate electrode 106. During annealing, or the like, the sacrificial metal layer 105 removes oxygen in the high-K dielectric layer 104 when it is converted into an oxide as a part of the dielectric layer. The sacrificial metal layer 105 consumes oxygen in the gate stack and thus reduces an amount of oxygen, which otherwise reacts with silicon (Si) or germanium (Ge) in the semiconductor substrate 101. The sacrificial metal layer 105 suppresses the formation of the interfacial oxide layer and minimizes the equivalent oxide thickness (EOT) of the gate dielectric layer.

However, in either of the gate-first process and the gate-last process, the above-mentioned semiconductor device still has the following drawbacks.

1. The sacrificial metal layer (i.e. the sacrificial metal layer 140) is converted into an oxide layer (which is a part of the dielectric layer) while oxygen in the dielectric layer (i.e. the high-K dielectric layer 130) is removed by an oxidation reaction with the sacrificial metal layer. However, the oxide layer still contributes to an increased EOT value.

2. If the sacrificial metal layer is not completely converted into an oxide layer, for example, due to an insufficient amount of oxygen, the remaining metal will be part of the metal gate electrode, which causes variations in work function for different semiconductor devices.

A transistor structure is disclosed in the U.S. Patent Application No. US2004/0164362A1 by John F., Conley JR., et al. In the transistor structure, a metal barrier layer is deposited between a metal gate electrode and a gate dielectric layer to prevent oxygen from diffusing into the metal gate electrode from the gate dielectric layer. The metal barrier layer is made of materials which inhibit oxygen diffusion. The metal barrier layer is deposited at a location corresponding to the location where the sacrificial metal layer is deposited in the above-mentioned conventional semiconductor device, but has a function opposite to the sacrificial metal layer. Consequently, an interfacial oxide layer, as described above, still exists in the transistor structure. The metal barrier layer cannot minimize the EOT value of the gate dielectric layer.

A gate structure comprising a sacrificial metal layer is disclosed by the present applicant in the Chinese Patent Application No. 201010197080.6, filed on Jun. 3, 2010. In the gate structure, a sacrificial metal layer is deposited on sidewalls of a gate stack, between a gate stack and insulating gate sidewall spacers, rather than being as a part of the gate stack as shown in FIG. 1. An oxide layer is formed by an oxidation reaction of the sacrificial metal layer during annealing, but does not contribute to the EOT value increase. Thus, the gate structure overcomes the first aspect of the above drawbacks. Moreover, the metal gate electrode has a small contact area with the remaining metal after the oxidation reaction of the sacrificial metal layer. Thus, the gate structure alleviates the second aspect of the above drawbacks.

One skilled person still expects to minimize the EOT value of the gate dielectric layer while well controlling the work function of the metal gate electrode in the processes for manufacturing CMOS FETs.

### SUMMARY

To overcome the above drawbacks of the conventional processes, the present invention provides a gate structure comprising a sacrificial metal layer and a method for manufacturing the same. The sacrificial metal layer is deposited along sidewalls of a gate stack such that oxygen in a high-K dielectric layer is removed by an oxidation reaction with the sacrificial metal layer.

According to one aspect of the present invention, there is provided a gate structure, comprising: a gate stack formed on a semiconductor substrate, the gate stack comprising an interfacial oxide layer, a high-K dielectric layer and a metal gate electrode from bottom to top; a first dielectric layer on sidewalls of the gate stack, the first dielectric layer serving as first sidewall spacers; and a sacrificial metal layer on sidewalls of the first dielectric layer, the sacrificial metal layer serving as second sidewall spacers.

According to another aspect of the present invention, there is provided a method for manufacturing a gate structure, comprising: forming a gate stack on a semiconductor substrate, the gate stack comprising an interfacial oxide layer, a high-K dielectric layer and a metal gate electrode from bottom to top; conformally forming a first dielectric layer on the semiconductor substrate and on the gate stack; conformally forming a sacrificial metal layer on the first dielectric layer; forming second sidewall spacers on sidewalls of the first dielectric layer by etching the sacrificial metal layer; and forming first sidewall spacers on sidewalls of the gate stack by etching the first dielectric layer.

In accordance with the present invention, during the annealing, the sacrificial metal layer may react to the oxygen which is generated in the high-K dielectric layer and in the thin interfacial oxide layer and diffused into the sacrificial metal layer through the first thin dielectric layer, in an oxidation reaction. The sacrificial metal layer suppresses diffusion of oxygen into the semiconductor substrate, which in turn suppresses formation of the interfacial oxide layer. Moreover, due to the electric isolation by the first dielectric layer, the sacrificial metal layer does not adversely affect the work function of the metal gate electrode. The present invention overcomes the drawbacks that the sacrificial metal layer increases the EOT value and cause an unpredictable work function in a conventional semiconductor device.

### BRIEF DESCRIPTION OF THE DRAWINGS

The above and other objects, features and advantages of the present invention will become clearer from the following description for preferred embodiments of the present invention, with reference to the attached drawings, in which:

FIG. 1 schematically shows a conventional semiconductor device comprising a sacrificial metal layer;

FIGS. 2a-2f schematically show various steps of the method for manufacturing a gate structure according to the first embodiment of the present invention; and

FIGS. 3a-3e schematically show various steps of the method for manufacturing a gate structure according to the second embodiment of the present invention.

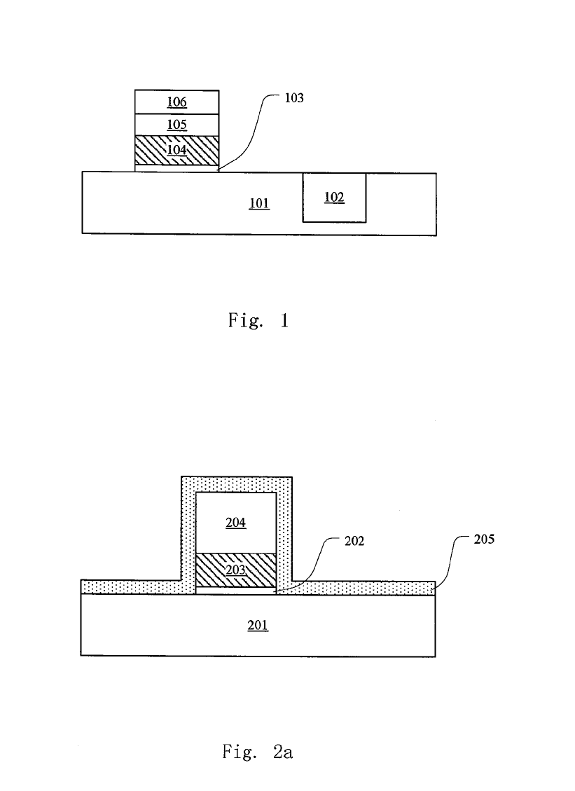

### DETAILED DESCRIPTION

Hereinafter, the present invention will be described with those preferred embodiments in connection with the attached drawings. However, it should be understood that the description is only illustrative, but not intended to limit the protection scope.

Furthermore, the description for those well-known structures and technologies are omitted so as to not unnecessarily obscure concepts of the present invention. For the purpose of clarity, various components in the attached drawings are not drawn to scale.

It should be understood that for a device structure, in a case that one layer or region are described as being located “on” or “above” another layer or region, it means that the one layer or region is on the another layer or region, either directly or with other layers or regions between the one layer or region and the another layer or region. Moreover, if the device structure is turned over, the one layer or region will be located “under” or “beneath” the another layer or region.

In a case that the one layer or one region is directly on the another layer or region, the expressions will be “directly on” or “on and adjacent to . . . ” herein.

The term “semiconductor structure” is used herein for generally designating intermediate structures and a final structure of the semiconductor device. The intermediate structures and a final structure of the semiconductor device are formed in various steps of the manufacturing method, and include a semiconductor substrate and all layers/regions formed thereon.

The term “sacrificial metal layer” is used herein for designating a metal layer which reacts to the oxygen from a gate dielectric layer in an oxidation reaction during annealing. That is, the “sacrificial metal layer” is a layer for consuming oxygen by an oxidation reaction. The “sacrificial metal layer” can also be referred to as an “oxygen removing layer” herein.

Some particular details of the present invention will be described below, such as an exemplary semiconductor structure, material, dimension, process step and fabricating method of the device, for a better understanding of the present invention. Nevertheless, it should be understood by one skilled person in the art that these details are not always essential for but may be varied in a specific implementation of the present invention.

Unless the context clearly indicates otherwise, each part of the semiconductor device may be made of material(s) well known to one skilled person in the art.

### The First Embodiment

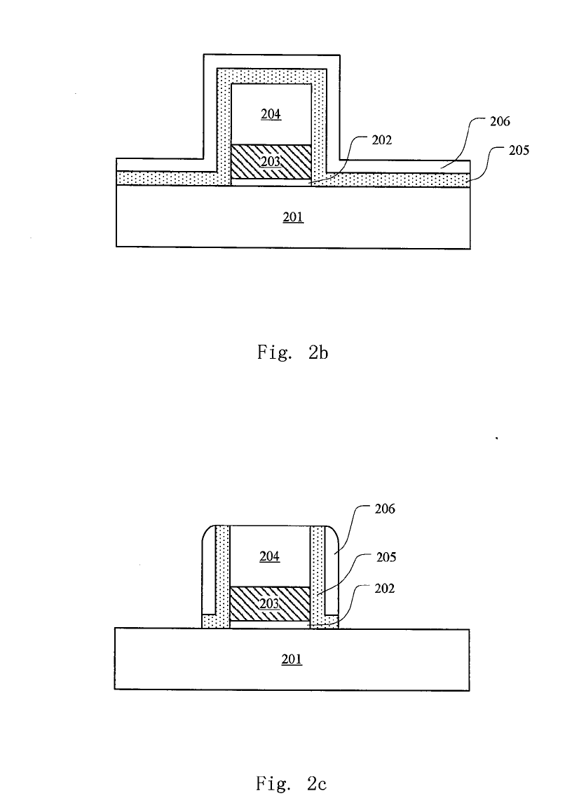

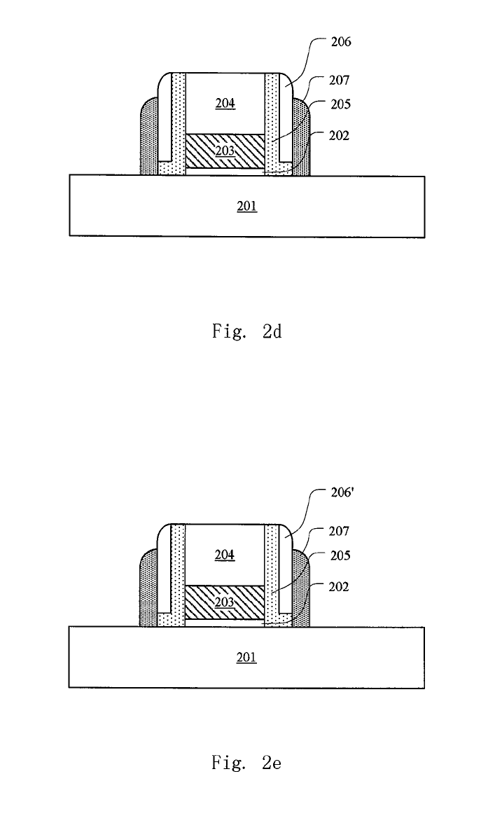

Hereinafter, various steps of the method for manufacturing a gate structure according to the first embodiment of the present invention will be described in detail with reference to FIGS. 2a-2f.

The method for manufacturing a gate structure according to the first embodiment of the present invention may be used either in a gate-first process to form a gate structure of a semiconductor device directly, or in a gate-last process to form a replacement gate of a semiconductor device. In the gate-last process, a dummy gate can still be formed by a conventional process.

It is apparent for one skilled person how to incorporate the method for manufacturing a gate structure into the gate-first process or the gate-last process. Therefore, the process steps for forming other parts of a CMOS FET, such as source/drain regions, inter-layer dielectric layers, vias, and electric contacts, will not be described in detail hereinafter, even in connection with the method for manufacturing a gate structure.

Referring to FIG. 2a, after a gate stack comprising an interfacial oxide layer 202, a high-K dielectric layer 203 and a metal gate electrode 204 is formed on a semiconductor substrate 201, a first dielectric layer 205 is conformally formed on the whole surface of the semiconductor structure by a conventional deposition process, such as, PVD, CVD, atomic layer deposition, sputtering, or the like. The first dielectric layer 205 has a thickness less than 3 nm.

The semiconductor substrate 201 may be made of any suitable materials used for semiconductor substrate, for example, Group IV semiconductor (such as Si, Ge, SiGe or SiC), or Group III-V semiconductor (such as GaAs, InP or GaN). The semiconductor substrate may be a bulk silicon substrate or a top semiconductor layer of an SOI wafer. In view of design requirements for semiconductor devices (for example, conductivity types of MOSFETs), the semiconductor substrate 201 per se may be doped. The semiconductor substrate 201 may comprise optional epitaxial layers, such as, a stress layer for applying stress.

The high-K dielectric layer 203 may be made of oxides, nitrides, oxynitrides, silicates, aluminates, titanates, or the like. The oxides include for example HfO₂, ZrO₂, Al₂O₃, TiO₂, and La₂O₃. The nitrides include for example Si₃N₄. The silicates include for example HfSiOₓ. The aluminates include for example LaAlO₃. The titanates include for example SrTiO₃. The oxynitrides include for example SiON. Additionally, the high-K dielectric layer 203 may be made not only of materials which are well known to those skilled in the art, but also of future-developed materials for the gate dielectric layer.

The metal gate electrode 204 may be made of any suitable metals, alloys or metal ceramics, which may comprise, for example, TaC, TiN, TaTbN, TaErN, TaYbN, TaSiN, HfSiN, MoSiN, RuTax, NiTax, MoNx, TiSiN, TiCN, TaAlC, TiAlN, TaN, PtSix, Ni₃Si, Pt, Ru, Ir, Mo, HfRu, RuOx or any combination thereof.

The first dielectric layer 205 may be made of oxides (for example, SiO₂, C-doped SiO₂), nitrides (for example, Si₃N₄), oxynitrides (for example, SiON) or any combination thereof.

Next, as shown in FIG. 2b, a sacrificial metal layer 206 is conformally formed on the whole surface of the semiconductor structure by the above-mentioned conventional deposition process. The sacrificial metal layer 206 has a thickness of about 1 nm to about 10 nm. The sacrificial metal layer 206 may be made of, for example, Al, Ta, La, Hf, Ti or any combination thereof, or any metal oxides thereof which are not fully oxidized and comprise oxygen.

Next, as shown in FIG. 2c, the portions of the sacrificial metal layer 206 and the first dielectric layer 205 that extend laterally are removed selectively from top to bottom by a selective dry etching process, such as plasma etching or reactive ion etching, without using a mask. The portions of the sacrificial metal layer 206 and the first dielectric layer 205 that extend along the sidewalls of the gate stack remain. The removed portions of the sacrificial metal layer 206 and the first dielectric layer 205 include the portions extending laterally on the semiconductor substrate 201 and the portions extending laterally on the gate stack. The remaining portions of the sacrificial metal layer 206 and the first dielectric layer 205 are deposited on the sidewalls of the gate stack to form sidewall spacers.

The above-mentioned dry etching process can include two steps for etching the sacrificial metal layer 206 and the first dielectric layer 205 under different processing conditions, respectively. In the first step where the sacrificial metal layer 206 is etched, the sacrificial metal layer 206 may be removed selectively and the etching can stop at the surface of the first dielectric layer 205 because of the selectivity of the etching. In the second step where the first dielectric layer 205 is etched, the sidewall spacers of the sacrificial metal layer 206 serve as a hard mask. Only the exposed portions of the first dielectric layer 205 are removed. The first dielectric layer 205 may be removed selectively and the etching can stop at the surface of the semiconductor substrate 201 because of the selectivity of the etching.

In the etching of the second step, the portions of the first dielectric layer 205 beneath the sacrificial metal layer 206 are protected and not removed. Consequently, the first dielectric layer 205 has a substantial L-shape cross section profile.

A typical configuration of the gate structure according to the first embodiment is formed in the above steps shown in FIGS. 2a-2c. This gate structure comprises the gate stack formed on the semiconductor substrate 201. The gate structure comprises the interfacial oxide layer 202, the high-K dielectric layer 203 and the metal gate electrode 204. The first dielectric layer 205 is deposited on the sidewalls of the gate stack to form first sidewall spacers. The sacrificial metal layer 206 is deposited on the sidewalls of the first dielectric layer 205 to form second sidewall spacers.

In the subsequent step of annealing, the sacrificial metal layer 206 reacts to the oxygen which is generated in the interfacial oxide layer 202 and in the high-K dielectric layer 203 and diffused into the sacrificial metal layer 206 through the first thin dielectric layer 205, in an oxidation reaction. The sacrificial metal layer 206 suppresses diffusion of oxygen into the underlying semiconductor substrate 201 is suppressed, which in turn suppresses formation of the interfacial oxide layer 202. Even if the interfacial oxide layer 202 is formed, the interfacial oxide layer 202 has a reduced thickness because the sacrificial metal layer 206 consumes most of oxygen. Moreover, due to the electric isolation by the first dielectric layer 205, the non-oxidized metal of the sacrificial metal layer 206 does not contact with the metal gate electrode 204, and thus does not adversely affect the work function of the metal gate electrode 204. As a result, one can choose suitable materials for the metal gate electrode 204 to have the required work function.

The gate structure according to the first embodiment of the present invention overcomes the drawbacks that the sacrificial metal layer increases the EOT value and cause an unpredictable work function in a conventional semiconductor device.

Preferably, as shown in FIG. 2d, third sidewall spacers are formed on the sidewalls of the sacrificial metal layer 206. For this, a second dielectric layer 207 is conformally formed on the whole surface of the semiconductor structure, and then, the portions of the second dielectric layer 207 that extend laterally are removed by above-mentioned selective dry etching process, without using a mask. The removed portions of the second dielectric layer 207 include the portions extending laterally on the semiconductor substrate and the portions extending laterally on the gate stack.

The second dielectric layer 207 may be made of oxides (for example, SiO₂, C-doped SiO₂), nitrides (for example, Si₃N₄), oxynitrides (for example, SiON) or any combination thereof. The second dielectric layer 207 may be made of a material the same as or different from that for the first dielectric layer 205.

The second dielectric layer 207 may be thicker than the first dielectric layer 205. For example, the second dielectric layer 207 may have a thickness of about 10 nm to about 60 nm. Therefore, the third sidewall spacers thus formed increase mechanical strength of the gate structure, and thus improve reliability of the semiconductor device.

Next, as shown in FIG. 2e, in the subsequent step of annealing, the sacrificial metal layer 206 reacts to the oxygen which is generated in the interfacial oxide layer 202 and in the high-K dielectric layer 203 and diffused into the sacrificial metal layer 206 through the first thin dielectric layer 205, in an oxidation reaction. At least a portion of the sacrificial metal layer 206 is converted into an oxide. FIG. 2e shows an example where the sacrificial metal layer 206 is converted into an oxide completely. Consequently, the sacrificial metal layer 206 becomes an insulating layer 206′, and constitutes gate sidewall spacers together with the first dielectric layer 205 and the second dielectric layer 207.

Preferably, as shown in FIG. 2f, after the step of annealing during which an oxidation reaction occurs, either the sacrificial metal layer 206 may be selectively removed from the gate structure shown in FIG. 2c, or the sacrificial metal layer 206 and the second dielectric layer 207 may be selectively removed from the gate structure shown in FIG. 2e, by a wet etching process in which an etchant is used. At least a portion of the sacrificial metal layer 206 has been converted into an oxide.

In a case that the sacrificial metal layer 206 is not fully oxidized, this preferred step can avoid a parasitic capacitance introduced by the sacrificial metal layer 206. In a case that an additional stress layer is used, this preferred step makes the stress layer come closer to the channel regions and improve the device performance by stress.

### The Second Embodiment

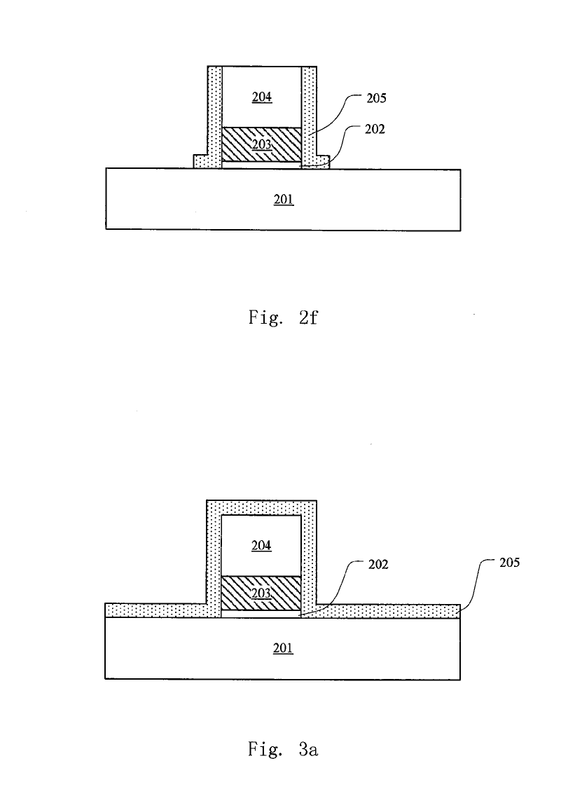

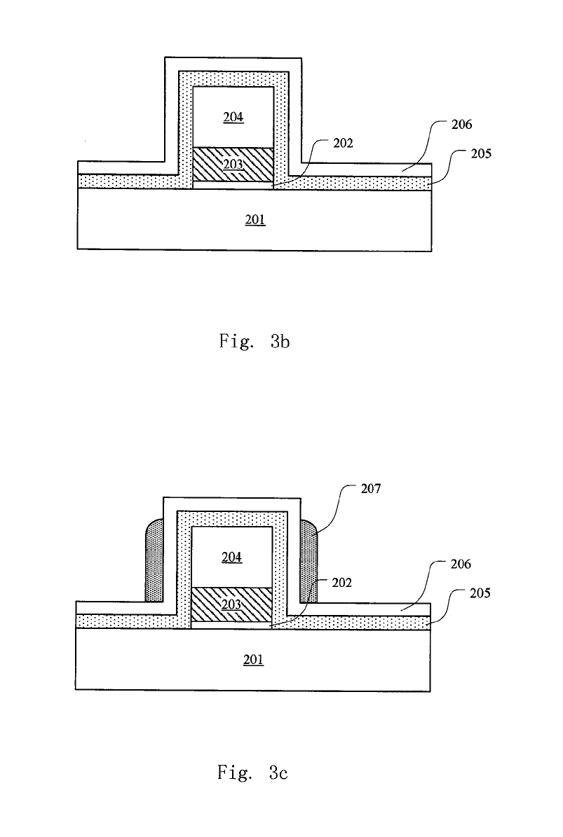

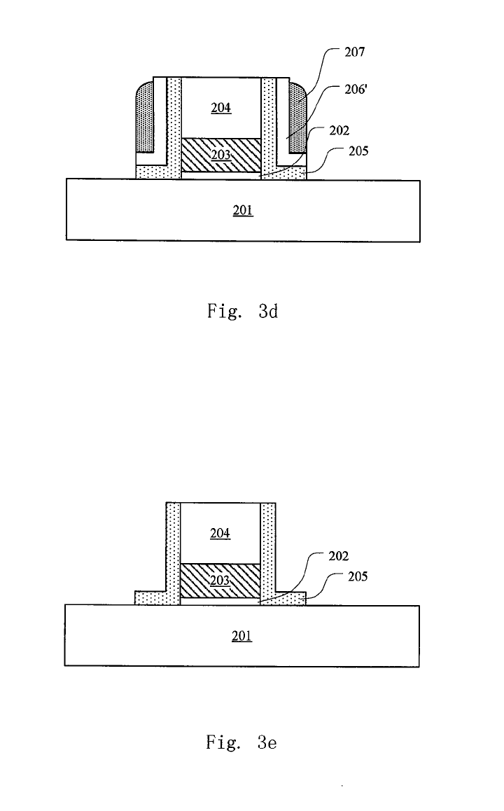

Hereinafter, various steps of the method for manufacturing a gate structure according to the second embodiment of the present invention will be described in detail with reference to FIGS. 3a-3e.

The method for manufacturing a gate structure according to the second embodiment of the present invention may be used either in a gate-first process to form a gate structure of a semiconductor device directly, or in a gate-last process to form a replacement gate of a semiconductor device. In the gate-last process, a dummy gate can still be formed by a conventional process.

It is apparent for one skilled person how to incorporate the method for manufacturing a gate structure into the gate-first process or the gate-last process. Therefore, the process steps for forming other parts of a CMOS FET, such as source/drain regions, inter-layer dielectric layers, vias, and electric contacts, will not be described in detail hereinafter, even in connection with the method for manufacturing a gate structure.

In the description of the second embodiment, those parts having been discussed in the first embodiment are denoted with the same reference numerals, and will not be described in detail below. Unless the context clearly indicates otherwise, the parts corresponding to those having been discussed in the first embodiment are made of the same materials and have the same thicknesses in the second embodiment.

FIGS. 3a and 3b show the process steps corresponding to the process steps shown in FIGS. 2a and 2b, respectively, in which a gate stack, a first dielectric layer 205 and a sacrificial metal layer 206 are formed on a semiconductor substrate 201.

Next, as shown in FIG. 3c, a second dielectric layer 207 is conformally formed on the whole surface of the semiconductor structure by a conventional deposition process. Subsequently, the portion of the second dielectric layer 207 that extends laterally is removed by a selective dry etching process, such as plasma etching or reactive ion etching, without using a mask. The portion of the second dielectric layer 207 that extends along the sidewalls of the gate stack remains. The removed portions of the second dielectric layer 207 include the portion extending laterally on the semiconductor substrate 201 and the portion extending laterally on the gate stack. The remaining portions of the second dielectric layer 207 are deposited on the sidewalls of sacrificial metal layer 206 to form third sidewall spacers.

Next, as shown in FIG. 3d, the portions of the sacrificial metal layer 206 and the first dielectric layer 205 that extend laterally are removed selectively from top to bottom by the above-mentioned selective dry etching process or the above-mentioned selective wet etching process in which an etchant is used, with the third sidewall spacers formed by the second dielectric layer 207 as a hard mask. The portions of the sacrificial metal layer 206 and the first dielectric layer 205 that extend on the sidewalls of the gate stack remain. The etching stops at the surface of the semiconductor substrate 201 because of the selectivity of the etching. The removed portions of the sacrificial metal layer 206 and the first dielectric layer 205 include the portions extending laterally on the semiconductor substrate 201 and the portions extending laterally on the gate stack. The remaining portions of the sacrificial metal layer 206 and the first dielectric layer 205 are deposited on the sidewalls of the gate stack to form sidewall spacers, respectively.

The portions of the sacrificial metal layer 206 and the first dielectric layer 205 beneath the second dielectric layer 207 are protected and not removed in this etching step. Consequently, the sidewall spacers formed by the sacrificial metal layer 206 and the first dielectric layer 205 each have a substantial L-shape cross section profile.

In the subsequent step of annealing, the sacrificial metal layer 206 reacts to the oxygen which is generated in the interfacial oxide layer 202 and in the high-K dielectric layer 203 and diffused into the sacrificial metal layer 206 through the first thin dielectric layer 205, in an oxidation reaction. At least a portion of the sacrificial metal layer 206 is converted into an oxide. FIG. 2e shows an example where the sacrificial metal layer 206 is converted into oxide completely. Consequently, the sacrificial metal layer 206 becomes an insulating layer 206′, and constitutes gate sidewall spacers together with the first dielectric layer 205 and the second dielectric layer 207.

A typical configuration of the gate structure according to the second embodiment is formed in the above steps shown in FIGS. 3a-3d. This gate structure comprises the gate stack formed on the semiconductor substrate 201. The gate structure comprises the interfacial oxide layer 202, the high-K dielectric layer 203 and the metal gate electrode 204. The first dielectric layer 205 is deposited on the sidewalls of the gate stack to form first sidewall spacers. The sacrificial metal layer 206 is deposited on the sidewalls of the first dielectric layer 205 to form second sidewall spacers. The second dielectric layer 207 is deposited on the sidewalls of the sacrifice metal layer 206 to form third sidewall spacers.

In the subsequent step of annealing, the sacrificial metal layer 206 reacts to the oxygen which is generated in the interfacial oxide layer 202 and in the high-K dielectric layer 203 and diffused into the sacrificial metal layer 206 through the first thin dielectric layer 205, in an oxidation reaction. The sacrificial metal layer 206 suppresses diffusion of oxygen into the underlying semiconductor substrate 201 is suppressed, which in turn suppresses formation of the interfacial oxide layer 202. Even if the interfacial oxide layer 202 is formed, the interfacial oxide layer 202 has a reduced thickness because the sacrificial metal layer 206 consumes most of oxygen. Moreover, due to the electric isolation by the first dielectric layer 205, the non-oxidized metal of the sacrificial metal layer 206 does not contact with the metal gate electrode 204, and thus does not adversely affect the work function of the metal gate electrode 204. As a result, one can choose suitable materials for the metal gate electrode 204 to have the required work function. The second dielectric layer 207 may be thicker than the first dielectric layer 205. Therefore, the third sidewall spacers thus formed increase mechanical strength of the gate structure, and thus improve reliability of the semiconductor device.

The gate structure according to the second embodiment of the present invention overcomes the drawbacks that the sacrificial metal layer increases the EOT value and cause an unpredictable work function in a conventional semiconductor device.

Compared with the first embodiment, the gate structure according to the second embodiment reduces the steps of etching in the manufacturing process. Moreover, the second dielectric layer 207 protects the sacrificial metal layer 206 in the steps of etching, which simplifies the manufacturing process and improves yield.

The step shown in FIG. 3e is the same one as that shown in FIG. 2f. Preferably, after the step of annealing during which an oxidation reaction occurs, the sacrificial metal layer 206 and the second dielectric layer 207 may be removed. At least a portion of the sacrificial metal layer 206 has been converted into an oxide.

In a case that the sacrificial metal layer 206 is not fully oxidized, this optional step can avoid a parasitic capacitance introduced by the sacrificial metal layer 206. In a case that an additional stress layer is used, this preferred step makes the stress layer come closer to the channel regions and improve the device performance by stress.

While the invention has been described with reference to specific embodiments, the description is illustrative of the invention. The description is not to be considered as limiting the invention. The description is not to be considered as limiting the invention. Various modifications and applications may occur for one skilled person without departing from the true spirit and scope of the invention as defined by the appended claims.

1. A gate structure, comprising:
a gate stack formed on a semiconductor substrate, the gate stack comprising a high-K dielectric layer and a metal gate electrode from bottom to top;
a first dielectric layer on sidewalls of the gate stack, the first dielectric layer serving as first sidewall spacers; and
a sacrificial metal layer on the first dielectric layer, the sacrificial metal layer serving as second sidewall spacers.

2. The gate structure according to claim 1, further comprising a second dielectric layer on the sacrificial metal layer, the second dielectric layer serving as third sidewall spacers.

3. The gate structure according to claim 1, wherein the first dielectric layer has a substantial L-shape cross section profile.

4. The gate structure according to claim 2, wherein the first dielectric layer has a substantial L-shape cross section profile.

5. The gate structure according to claim 4, wherein the sacrificial metal layer has a substantial L-shape cross section profile.

6. The gate structure according to claim 1, wherein the sacrificial metal layer has a thickness of about 1 nm to about 10 nm.

7. The gate structure according to claim 1, wherein the sacrificial metal layer is made of one selected from a group consisting of Al, Ta, La, Hf, and Ti, or combinations thereof, or any metal oxides thereof which are not fully oxidized and comprise oxygen.

8. The gate structure according to claim 1, wherein the first dielectric layer has a thickness less than about 3 nm.

9. The gate structure according to claim 1, wherein the first dielectric layer is made of one selected from a group consisting of SiO₂, Si₃N₄, SiON, and C-doped SiO₂, or combinations thereof.

10. The gate structure according to claim 1, wherein the second dielectric layer has a thickness of about 10 nm to about 60 nm.

11. The gate structure according to claim 1, wherein the second dielectric layer is made of one selected from a group consisting of SiO₂, Si₃N₄, SiON, and C-doped SiO₂, or combinations thereof.

12. The gate structure according to claim 1, wherein at least a portion of the sacrificial metal layer is converted into oxides.

13. A method for manufacturing a gate structure, comprising:
forming a gate stack on a semiconductor substrate, the gate stack comprising a high-K dielectric layer and a metal gate electrode from bottom to top;
conformally forming a first dielectric layer on the semiconductor substrate and on the gate stack;
conformally forming a sacrificial metal layer on the first dielectric layer;
forming second sidewall spacers on the first dielectric layer by etching the sacrificial metal layer; and
forming first sidewall spacers on sidewalls of the gate stack by etching the first dielectric layer.

14. The method according to claim 13, wherein in the step of forming the first sidewall spacers, the etching is performed with the second sidewall spacers as a hard mask.

15. The method according to claim 13, wherein after the step of forming the first sidewall spacers, the method further comprises conformally forming a second dielectric layer on the semiconductor substrate and on the sacrificial metal layer; and forming third sidewall spacers on the sacrificial metal layer by etching the second dielectric layer.

16. The method according to claim 13, wherein between the step of forming the sacrificial metal layer and the step of forming the second sidewall spacers, the method further comprises: conformally forming a second dielectric layer on the semiconductor substrate and on the sacrificial metal layer; and forming third sidewall spacers on the sacrificial metal layer by etching the second dielectric layer.

17. The method according to claim 16, wherein in the steps of forming the second sidewall spacers and forming the first sidewall spacers, the etching is performed with the third sidewall spacers as a hard mask.

18. The method according to claim 13, wherein after the step of forming the second sidewall spacers, the method further comprises annealing the semiconductor device, wherein during the annealing, the sacrificial metal layer reacts to the oxygen which is generated in the high-K dielectric layer and diffused into the sacrificial metal layer through the first dielectric layer in an oxidation reaction.

19. The method according to claim 18, wherein after the annealing, the method further comprises removing the sacrificial metal layer by etching.

20. The method according to claim 18, wherein the gate stack further comprises an interfacial oxide layer below the high-K dielectric layer.

21. The method according to claim 19, after the step of forming the second sidewall spacers, the method further comprises annealing the semiconductor device, wherein during the annealing, the sacrificial metal layer reacts to the oxygen which is generated in the high-K dielectric layer and in the interfacial oxide layer and diffused into the sacrificial metal layer through the first dielectric layer, in an oxidation reaction.

22. The gate structure according to claim 1, wherein the gate stack further comprises an interfacial oxide layer below the high-K dielectric layer.
